(19) United States
(12) Patent Application Publication
(10) Pub. No.: US 2007/0074757 A1
(43) Pub. Date: Apr. 5, 2007

(54) Method of making solar cell/module with porous silica antireflective coating

(75) Inventors: Nathan P. Mellott, Northville, MI (US); Thomas J. Taylor, Northville, MI (US)

Correspondence Address: NIXON & VANDERHYE, PC, 901 NORTH GLEBE ROAD, 11TH FLOOR, ARLINGTON, VA, 22203, US

(73) Assignee: Gurdian Industries Corp, Auburn Hills, MI (US)

(21) Appl. No.: 11/242,123

(22) Filed: Oct. 4, 2005

(51) Int. Cl. H01L 31/00

(52) U.S. Cl. 136/256

(57) ABSTRACT

A solar cell includes an improved anti-reflection (AR) coating provided on an incident glass substrate. In certain example embodiments, the AR coating includes a layer comprising porous silica. The porous nature of the silica inclusive layer permits the refractive index (n) of the silica inclusive layer to be reduced, thereby decreasing reflection and permitting more radiation to make its way to the active layer(s) of the solar cell. In certain example embodiments, a coating solution may be formed by mixing a colloidal silica solution and a polymeric silica solution, then applying the coating solution to a substrate and curing the same in order to form an AR coating.

This invention relates to an antireflective (AR) coating that may be used in applications such as solar and/or photovoltaic modules and/or cells. In certain instances, a module may include a cell, and photovoltaic and solar may be used interchangeably. In certain example embodiments, a solar cell and/or module is provided with a glass substrate supporting an AR coating, the AR coating being of or including porous silica so as to reduce the coating's index of refraction (n) thereby increasing the amount of radiation which makes its way through the glass substrate to the active portions of the solar cell and/or module. In certain example embodiments, a coating solution may be formed by mixing a colloidal silica solution and a polymeric silica solution, then applying the coating solution to a substrate and curing the same in order to form an AR coating.

### BACKGROUND OF THE INVENTION

Solar cells/modules are known in the art. A solar cell/module may include, for example, a photoelectric transfer film made up of one or more layers located between a pair of substrates. These layers may be supported by a glass substrate. Example solar cells are disclosed in U.S. Pat. Nos. 4,510,344, 4,806,436, 6,506,622, 5,977,477, and JP 07-122764, the disclosures of which are hereby incorporated herein by reference.

Substrate(s) in a solar cell/module are sometimes made of glass. Incoming radiation passes through the incident glass substrate of the solar cell before reaching the active layers (e.g., photoelectric transfer film such as a semiconductor) of the solar cell. Radiation that is reflected by the incident glass substrate does not make its way into the active layer(s) of the solar cell thereby resulting in a less efficient solar cell. In other words, it would be desirable to decrease the amount of radiation that is reflected by the incident substrate, thereby increasing the amount of radiation that makes its way to the active layer(s) of the solar cell.

Thus, in certain example embodiments of this invention, an improved anti-reflection (AR) coating is provided on an incident glass substrate of a solar cell or the like.

### BRIEF SUMMARY OF EXAMPLE EMBODIMENTS OF THE INVENTION

In certain example embodiments of this invention, an improved anti-reflection (AR) coating is provided on an incident glass substrate of a solar cell/module or the like. In certain example embodiments, the AR coating includes a layer comprising porous silica. The porous nature of the silica inclusive layer permits the refractive index (n) of the silica inclusive layer to be reduced, thereby decreasing reflection and permitting more radiation to make its way to the active layer(s) of the solar cell/module.

In certain example embodiments of this invention, a silica (e.g., colloidal and/or polymeric precursors) coating solution is used to form an AR coating on glass. Such a coating may be used for any application where high light transmission in the wavelength range of from about 300 to 2500 nm, more preferably from about 400 to 1200 nm, is desired (e.g., solar cell/module applications).

In certain example embodiments of this invention, a coating solution is based on two different silica precursors, namely (a) a colloidal silica solution including or consisting essentially of particulate and/or colloidal silica in a solvent, and (b) a polymeric solution including or consisting essentially of silica chains and/or polymers. In making the polymeric silica solution, a silane may be mixed with a catalyst, solvent and water. After ageing, the colloidal silica solution (a) is added to the polymeric silica solution (b) in a solvent. The sol gel coating solution is then deposited on a suitable substrate such as a glass substrate. The coating on the glass substrate may be made up of or include a colloidal SiO₂ component (e.g., nanoparticulate dispersed in solvent) and a polymeric SiO₂ component (e.g., acid and/or H₂O catalyzed silane and solvent solution). Then, the sol gel coating solution on the glass substrate is fired from about 100 to 750 degrees C., thereby forming the solid AR coating on the glass substrate. The final thickness of the AR coating may be approximately a quarter wave thickness in certain example embodiments of this invention, although other thickness are possible.

In certain example embodiments, there is provided a method of making a solar cell/module comprising, the method comprising: providing a glass substrate; providing a colloidal silica solution comprising particulate/colloidal silica in at least one solvent; providing a polymeric solution comprising silica chains/polymers; mixing the colloidal silica solution and the polymeric solution comprising silica chains/polymers to form a coating solution; depositing the coating or coating solution on a glass substrate; curing the coating solution to form an anti-reflective coating on the glass substrate, said curing comprising heating the coating solution; and using the glass substrate with the anti-reflective coating provided thereon in a solar cell/module.

In other example embodiments of this invention, there is provided a method of making a coated article, the method comprising: providing a glass substrate; providing a colloidal silica solution comprising particulate/colloidal silica in at least one solvent; providing a polymeric solution comprising silica chains/polymers; mixing the colloidal silica solution and the polymeric solution comprising silica chains/polymers to form a coating or coating solution; depositing the coating solution on the glass substrate; and curing the coating solution to form an anti-reflective coating on the glass substrate, said curing comprising heating the coating solution.

In certain example embodiments of this invention, there is provided a method of making a solar cell/module, the method comprising: providing a glass substrate; coating the glass substrate with a sol-gel based silica precursor, and then subjecting the sol-gel to drying and baking so that following drying and baking an antireflective layer is present comprising a porous silica; and using the glass substrate coated with the antireflective layer in making a solar cell/module comprising first and second conductive layers with at least a photoelectric film provided therebetween, wherein the antireflective layer is provided on an incident side of the solar cell/module.

In other example embodiments of this invention, there is provided a solar cell comprising: first and second conductive layers with at least a photoelectric film provided therebetween; a glass substrate provided at an incident side of the solar cell, the glass substrate supporting an antireflective coating on an incident side of the glass substrate; and wherein the antireflective coating comprises a porous silica based layer. In certain example embodiments, the antireflective coating may be a single layer coating and have a refractive index (n) of from about 1.2 to 1.45, more preferably from about 1.2 to 1.38, even more preferably from about 1.25 to 1.35. In certain example instances, the antireflective coating is provided directly on and contacting the glass substrate, although in other instances another layer(s) may be provided on the glass substrate between the substrate and the porous silica based layer.

### BRIEF DESCRIPTION OF THE DRAWINGS

FIG. 1 is a side cross sectional view of a solar cell/module according to an example embodiment of this invention.

FIG. 2 is a side cross sectional view of a solar cell/module according to another example embodiment of this invention.

FIG. 3 is a simplified schematical diagram of reflective properties of radiation (e.g., light) incident on a glass substrate from surrounding air/atmosphere.

FIG. 4 is a cross sectional schematic diagram of principles and structure of an AR coating based on a destructive interference approach.

FIG. 5 is a graph illustrating the refractive index (n) of the coating of Example 1, as a function of angle.

FIG. 6 is a graph comparing the transmission spectra of (i) uncoated glass, (ii) the glass coated with the AR coating of Example 1, and (iii) the glass coated with the AR coating of Example 1 after the coating has been subjected to a durability test.

FIG. 7 is a graph comparing the reflection spectra of (i) uncoated glass, and (ii) the glass coated with the AR coating of Example 1.

FIG. 8 is a graph illustrating optical characteristics of the coated article of Example 1.

### DETAILED DESCRIPTION OF EXAMPLE EMBODIMENTS OF THE INVENTION

In certain example embodiments of this invention, a silica (e.g., colloidal and/or polymeric precursors) coating solution is used to form an AR coating on glass. Such a coating may be used for any application where high light transmission in the wavelength range of from about 280 to 2500 nm, more preferably from about 400 to 1200 nm, is desired (e.g., solar cell/module applications, also known as photovoltaic devices or modules).

Glass is used in different applications for numerous reasons, including optical clarity and overall visual appearance. For some applications, certain optical properties (e.g., one or more of transmission, reflection and/or absorption) are optimized. For example, reduction or minimization of reflection from the surface of glass is often desirable in applications such as storefront windows, display cases, picture frames and solar cells (or photovoltaic modules).

Glass is used in many different types of solar cells/modules, including both crystalline and thin film types of solar cells. The glass often is used to form the incident substrate on the light incident side of the active layer(s) of the solar cell, thereby protecting the active layer(s) which convert solar energy to electricity.

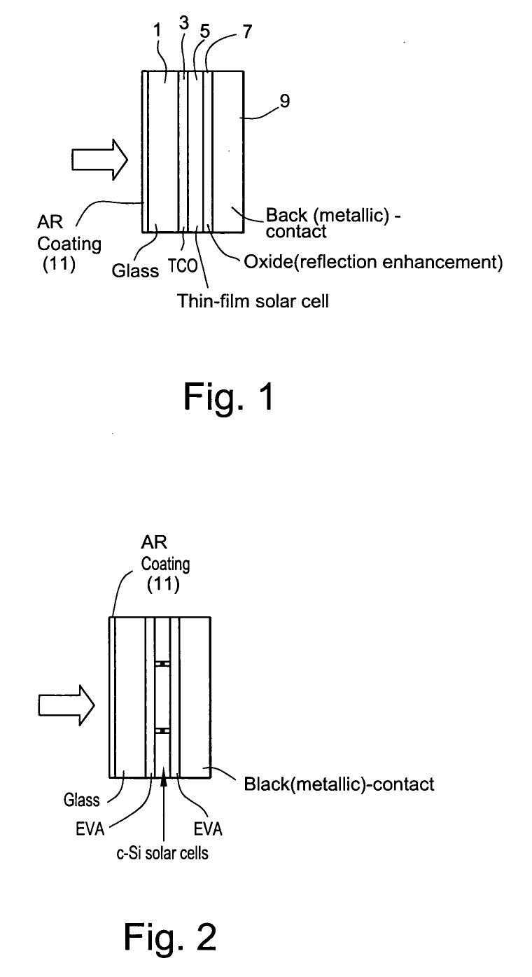

FIG. 1 is a schematic cross sectional diagram of a thin film solar cell/module according to an example embodiment of this invention, whereas FIG. 2 is a schematic cross sectional diagram of a crystalline type solar cell according to an example embodiment of this invention. The thin film solar cell of FIG. 1 includes incident glass substrate 1, front electrode 3 (e.g., made of a transparent conductive oxide, TCO, or other thin film conductor), active layer(s) 5 that convert solar radiation to electricity, oxide film 7, and back (e.g., metallic) contact 9. The power output of the solar cell module is dependant on the amount of radiation (number of photons) within the solar spectrum that passes through the glass 1 and reaches the photovoltaic semiconductor (or active layer(s)) 5. In this respect, solar transmission through the glass 1 can be improved through the use of an antireflection (AR) coating 11 on the incident surface of the glass (i.e., the surface of the glass 1 facing the surrounding atmosphere from which light comes) as shown in FIG. 1. FIG. 2 illustrates a solar cell of a different type, with a similar AR coating 11.

In certain example embodiments of this invention, AR coating 11 is of or includes a porous silica inclusive layer provided on the glass 1. The glass may be float glass in certain example embodiments of this invention, although other types of glass may instead be used. In certain example embodiments, the glass may be a low-iron, optionally patterned, type glass for higher transmission of solar radiation and photons thereof. As will be described below, the porous nature of the silica inclusive layer permits the refractive index (n) of the AR coating to be lowered, thereby reducing reflections off of the solar cell and improve the solar cell's power output and/or amount of light that comes in contact with the active photovoltaic semiconductor.

In a simplified case of two media (e.g., air and glass, or alternative air and an AR layer) irradiated with a single wavelength of radiation at normal incidence, reflection of radiation/light is due to an abrupt change in refractive index (n) experienced by the light packet or wave. The light reflection (R) is given by the Fresnel equation:
R=(n₂−n₁)²/(n₂+n₁)² (1)

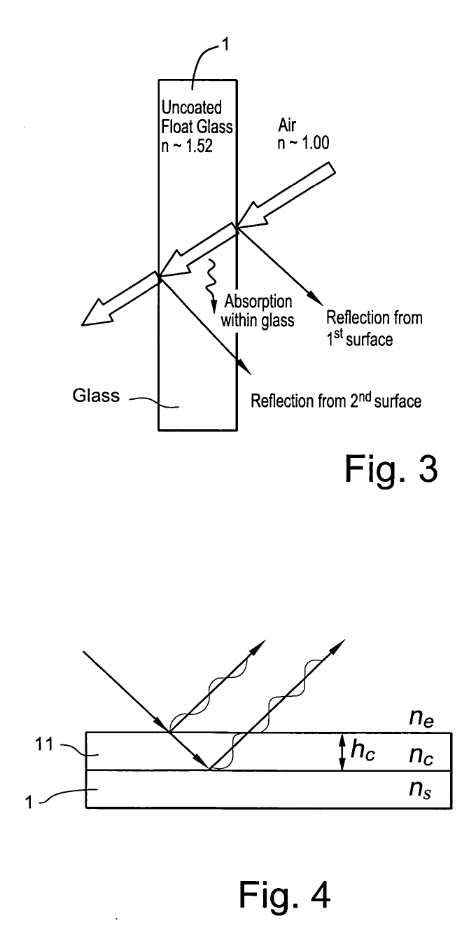

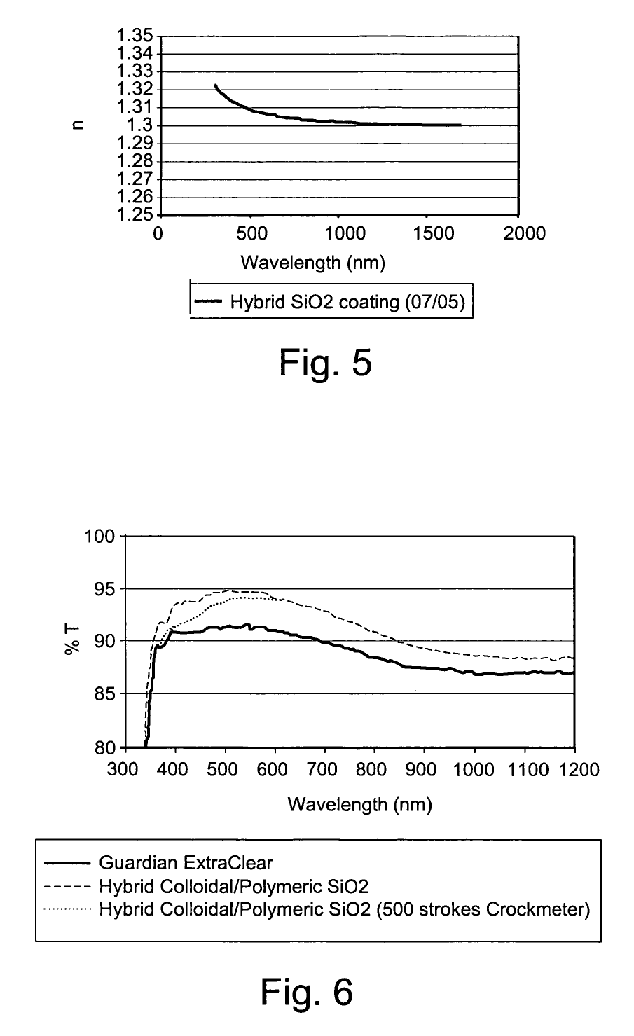

In this equation, n₁ is the refractive index of the media in which the light is traveling (exiting) and n₂ is the refractive index of the media in which the light is entering. FIG. 3 is a simplified air/glass system where radiation is traveling through the air, and hits a glass substrate. In an air/glass system, there is typically a 4-5% reflection from each surface and absorption within the glass 1 which can range from about 1-30% depending upon the wavelength of interest, the type of glass, and glass thickness.

The reflection of radiation/light from a glass surface can be decreased through numerous approaches. In certain example embodiments of this invention, the principle of destructive interference, or substantial destructive interference, is used to reduce the reflection of light from the glass surface for the incident glass of a solar cell or the like. In order to achieve complete destructive interference and hence optimal AR properties, an AR coating must satisfy two conditions: (a) amplitude, and (b) phase condition. The amplitude condition means that the amplitude of the light reflected from the coating/air and substrate/coating interfaces is equal, and is satisfied when the following equation is met:
n_{c}=(nₑnₛ)^{1/2} (2)

In equation (2), n_{c} is the refractive index of the coating, nₑ is the refractive index of the environment (e.g., air), and nₛ is the refractive index of the glass substrate. The refractive index of air is typically about 1.00, and that of glass is typically about 1.52. For a substantial destructive interference to be achieved, with respect to amplitude condition, equation (2) is met with a tolerance of plus or minus 25%, more preferably plus or minus 15% or even 10%.

The phase condition is that the length of the light's optical path in the layer is equal to half of the light wavelength, resulting in a quarter-wave condition. For a substantial destructive interference to be achieved, with respect to phase condition, the length of the light's optical path in the layer is approximately equal to half of the light wavelength (plus/minus about 15%, or more preferably plus/minus about 10%), resulting in an approximate or substantial quarter-wave condition. Therefore, the ideal thickness of an AR coating (h_{c}) with a given refractive index (n_{c}) is as follows:
h_{c}=λₒ/4n_{c} (3)

FIG. 4 illustrates the ideal thickness of the coating exemplified by equation (3), where λₒ is the wavelength at which the destructive interference occurs, n_{c} is the refractive index of the AR coating 11, and h_{c} is the ideal thickness of the AR coating 11.

Using the above relationships (1), (2) and (3), if 550 nm light is considered for example and without limitation (with a glass substrate 1 having an index n of 1.52), then the ideal AR coating 11 would have a refractive index of approximately 1.23 and a thickness of this coating 11 would be approximately 100 nm, with a certain minimal spatial thickness variation. However, the use of a single-layer AR coating on glass based on the destructive interference approach is disadvantageous in that there is no known dense, inorganic, heat-treatable (e.g., temperable) solid which can satisfy this requirement for a refractive index of about 1.23. Where a particular degree of reflectance can be tolerated, MgF₂ as an AR coating has a refractive index (n) of about 1.38 and may be used. When MgF₂ as an AR coating 11 is deposited on float glass 1 at a quarter wavelength thickness of about 110 nm, roughly a 1.5% reflectance per face will result. This may be satisfactory in certain example instances. However, in other example embodiments of this invention, this 1.5% reflectance and/or n of about 1.38 can be improved upon (i.e., reflectance and/or refractive index can be lowered in certain example embodiments of this invention).

An example approach to decrease the refractive index (n) of the AR layer 11 is to add porosity to the solid of the layer. This is effective given that air has a refractive index of about 1.0. For example, a completely dense layer of SiO₂ has a refractive index (n) of about 1.46, and if deposited at a quarter wavelength thickness (about 100 nm) on glass approximately 3.0% reflection per face will result. However, through careful optimization of porosity of such a silica inclusive layer, the refractive index can be lowered to a point at which it may be used as a single layer AR coating 11, resulting in a complete or substantial destructive interference.

The use of single layer, sol-gel based porous silica as an AR coating solution for glass is known. However, such conventional coatings are typically based on precursor solutions based on colloidal silica or silica particles, or precursors based on polymeric or colloidal silica solutions, doped with surfactants. Many such coatings do not have acceptable mechanical/abrasion resistance.

In order to address such problems, example embodiments of this invention provide a new method to produce a porous silica coating, with appropriate light transmission and abrasion resistance properties. Such coatings may be used in applications such as solar cells/modules. In certain example embodiments of this invention, the coating solution is based on two different silica precursors, namely (a) a colloidal silica solution including or consisting essentially of particulate silica in a solvent, and (b) a polymeric solution including or consisting essentially of silica chains. In making the polymeric silica solution, a silane may be mixed with a catalyst, solvent and water. After ageing, the colloidal silica solution (a) is added to the polymeric silica solution (b) with a solvent. The sol gel coating solution is then deposited on a suitable substrate such as a highly transmissive clear glass substrate. Then, the sol gel coating solution on the glass 1 substrate is fired from about 100 to 750 degrees C., thereby forming the solid AR coating on the glass substrate. The final thickness of the AR coating 11 may be approximately a quarter wave thickness in certain example embodiments of this invention. It has surprisingly been found that an AR coating made in such a manner had adequate durability, thereby overcoming the aforesaid mechanical/abrasion resistance problems.

Thus, in certain example embodiments, the liquid coating solution is formed by mixing (a) a colloidal silica solution including or consisting essentially of silica particulates and/or colloids in a solvent, and (b) a polymeric solution including or consisting essentially of silica chains and/or polymers, and may be known as a hybrid solution. The solution is stirred, deposited on a glass substrate, a fired/cured by heating to form the AR coating 11. In certain example embodiments, the colloidal silica solution may be of or include from about 5-60%, more preferably 10 to 50%, particulate SiO₂ (more preferably from about 20-40%, and most preferably from about 25-35% SiO₂), with the remainder or substantially the remainder being made up of solvent. The average silica particle size in the colloidal silica solution may be from about 1-150 nm, more preferably 5-50 nm, even more preferably from about 10-15 nm, in certain example embodiments of this invention. The polymeric solution in certain example embodiments of this invention may be of or include from about 45-95% solvent such as propanol (more preferably from about 60-80%, and most preferably from about 65-75%), from about 10-50% of a silane such as γ glycidoxypropyl-trimethoxysilane (more preferably from about 15-35%, and most preferably from about 20-30%), from about 1-20% water (more preferably from about 5-15%, and most preferably from about 5-10%), and from about 1-20% acid such as HCl (more preferably from about 2-10%, and most preferably from about 4-7%). A solvent may be used to dilute the coating solution in certain example instances.

In certain example embodiments, the AR coating 11 formed in such a manner may result in an average increase in transmission between 280-2500 nm of at least 0.5%, more preferably at least 1.5%, more preferably at least 2.0%, and most preferably at least 2.5%. In certain example solar cell/module applications, the AR coating 11 formed on the glass substrate 1 in such a manner may result in an increased energy output (W/m²) for a crystalline silicon based solar cell of at least about 1.0%, more preferably at least about 1.5%, even more preferably at least about 2.0%, more preferably at least about 3.0%, at standard test conditions (AM 1.5 at noon), and/or at least a 3.0% (more preferably at least 3.5%) daily increase (AM 1.5 sunrise to sunset).

Porous silica AR layers 11 may be formed in different ways in different example embodiments of this invention. In certain example embodiments of this invention, the AR coating 11 may be formed as discussed above by applying a liquid coating solution based on two different silica precursors, namely (a) a colloidal silica solution including or consisting essentially of particulate and/or colloidal silica in a solvent, and (b) a polymeric solution including or consisting essentially of silica chains and/or polymers, to a glass substrate. After firing (heating), a solid AR coating 11 results on the glass substrate 1. In other example embodiments, a sol-gel layer may be formed on a glass substrate (e.g., including for example TEOS: water: acetic acid: and solvent such as propanol or MEK), dried and baked. In certain example embodiments, hydrolysis is permitted before use. It will be appreciated that the solvent burns off or evaporates during the curing process in order to form porosity in the AR layer (i.e., to make the layer less dense and thus porous to some extent). The density of the AR layer 11 may be from about 40-95% in certain example embodiments of this invention, more preferably from about 50-90%, and most preferably from about 50-75% (compared to a typical or normal SiO₂ layer deposited by sputtering or the like). The AR layer/coating 11 may in certain example embodiments of this invention have a refractive index (n) of from about 1.2 to 1.35, more preferably from about 1.2 to 1.32, and most preferably from about 1.2 to 1.28.

In certain example embodiments of this invention, the porous silica based layer may be formed by techniques such as: (i) applying a liquid or sol gel coating solution based on two different silica precursors, namely a colloidal silica solution including or consisting essentially of particulate and/or colloidal silica in a solvent, and a polymeric solution including or consisting essentially of silica chains and/or polymers, with subsequent curing, or (ii) other suitable technique(s).

In certain example embodiments of this invention, the antireflective coating 11 increases energy output of the solar cell/module by at least 1.0% compared to if the glass substrate was uncoated on the incident side thereof (more preferably by at least about 1.5%, and most preferably by at least about 2.0%).

### EXAMPLE 1

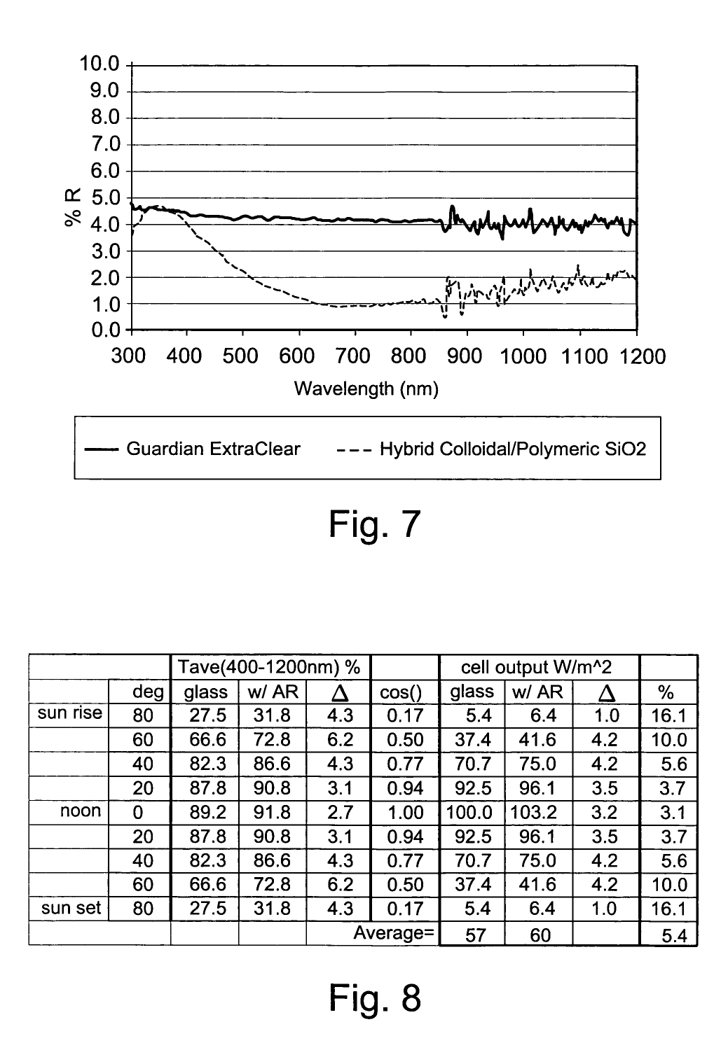

In Example 1, a polymeric silica solution (weight %: 64% n-propanol, 24% γ-glycidoxypropyl-trimethoxysilane, 7% H₂O, and 5% HCl) was stirred at room temperature for about 24 hours. A colloidal silica solution was used, and in this example is known as MEK-ST silica from Nissan Chemical (weight %: 30% SiO₂, 10-15 nm particle size). The coating solution was made by mixing 74% n-propanol, 19.3% of the polymeric silica solution mentioned above, and 6.7% of the colloidal silica solution mentioned above, and stirring the same. This coating solution was deposited on a 3.1 mm thick clear glass substrate (ExtraClear Glass from Guardian Industries Corp.), and was then cured at about 220 degrees C. for about 9 minutes. The sample was then transferred to a belt furnace (max temperature 625 degrees C.), thereby resulting in a coated article including AR coating 11 on glass substrate 1. FIG. 6 illustrates the refractive index (n), as a function of angle, of the AR coating of Example 1. FIG. 7 illustrates the transmission spectra of the 3.1 mm thick glass with the AR coating thereon of Example 1, with the dotted line indicating the spectra after 500 strokes in a Crockmeter to illustrate durability (the dark line in FIG. 7 is the glass itself without the coating). FIG. 8 illustrates the reflection (R) spectra of the 3.1 mm thick glass with the AR coating thereon of Example 1 (the dark line in FIG. 8 is the glass itself without the coating). FIG. 9 illustrates optical characteristics of the coated article of Example 1. It can be seen that the coating 11 of Example 1 results in about a 2.7% average increase in transmission between about 400-1200 nm, and hence about a 2.7% average decrease in reflectance from about 400-1200 nm. This results in a theoretical energy output (W/m²) increase for a crystalline silicon based photovoltaic cell of about 3.1% at standard test conditions (AM 1.5 at noon) and a 5.4% daily increase (AM 1.5 sunrise to sunset) as shown in FIG. 9.

In certain example embodiments of this invention, high transmission low-iron glass may be used for glass substrate 1 in order to further increase the transmission of radiation (e.g., photons) to the active layer of the solar cell. For example and without limitation, the glass substrate 1 may be of any of the glasses described in any of U.S. patent application Ser. Nos. 11/049,292 and/or 11/122,218, the disclosures of which are hereby incorporated herein by reference.

Certain glasses for glass substrate 1 (which or may not be patterned in different instances) according to example embodiments of this invention utilize soda-lime-silica flat glass as their base composition/glass. In addition to base composition/glass, a colorant portion may be provided in order to achieve a glass that is fairly clear in color and/or has a high visible transmission. An exemplary soda-lime-silica base glass according to certain embodiments of this invention, on a weight percentage basis, includes the following basic ingredients:

### EXAMPLE BASE GLASS

| Ingredient | Wt. % |
|---|---|
| SiO₂ | 67-75% |
| Na₂O | 10-20% |
| CaO | 5-15% |
| MgO | 0-7% |
| A1₂O₃ | 0-5% |
| K₂O | 0-5% |
| Li₂O | 0-1.5% |
| BaO | 0-1% |

Other minor ingredients, including various conventional refining aids, such as SO₃, carbon, and the like may also be included in the base glass. In certain embodiments, for example, glass herein may be made from batch raw materials silica sand, soda ash, dolomite, limestone, with the use of sulfate salts such as salt cake (Na₂SO₄) and/or Epsom salt (MgSO₄×7H₂O) and/or gypsum (e.g., about a 1:1 combination of any) as refining agents. In certain example embodiments, soda-lime-silica based glasses herein include by weight from about 10-15% Na₂O and from about 6-12% CaO.

In addition to the base glass above, in making glass according to certain example embodiments of the instant invention the glass batch includes materials (including colorants and/or oxidizers) which cause the resulting glass to be fairly neutral in color (slightly yellow in certain example embodiments, indicated by a positive b* value) and/or have a high visible light transmission. These materials may either be present in the raw materials (e.g., small amounts of iron), or may be added to the base glass materials in the batch (e.g., cerium, erbium and/or the like). In certain example embodiments of this invention, the resulting glass has visible transmission of at least 75%, more preferably at least 80%, even more preferably of at least 85%, and most preferably of at least about 90% (sometimes at least 91%) (Lt D65). In certain example non-limiting instances, such high transmissions may be achieved at a reference glass thickness of about 3 to 4 mm In certain embodiments of this invention, in addition to the base glass, the glass and/or glass batch comprises or consists essentially of materials as set forth in Table 2 below (in terms of weight percentage of the total glass composition):

### EXAMPLE ADDITIONAL MATERIALS IN GLASS

| | | | Most |
|---|---|---|---|
| Ingredient | General (Wt. %) | More Preferred | Preferred |
| total iron | 0.001-0.06% | 0.005-0.04% | 0.01-0.03% |
| (expressed as Fe₂O₃): | | | |
| cerium oxide: | 0-0.30% | 0.01-0.12% | 0.01-0.07% |
| TiO₂ | 0-1.0% | 0.005-0.1% | 0.01-0.04% |

In certain example embodiments, the total iron content of the glass is more preferably from 0.01 to 0.06%, more preferably from 0.01 to 0.04%, and most preferably from 0.01 to 0.03%. In certain example embodiments of this invention, the colorant portion is substantially free of other colorants (other than potentially trace amounts). However, it should be appreciated that amounts of other materials (e.g., refining aids, melting aids, colorants and/or impurities) may be present in the glass in certain other embodiments of this invention without taking away from the purpose(s) and/or goal(s) of the instant invention. For instance, in certain example embodiments of this invention, the glass composition is substantially free of, or free of, one, two, three, four or all of: erbium oxide, nickel oxide, cobalt oxide, neodymium oxide, chromium oxide, and selenium. The phrase “substantially free” means no more than 2 ppm and possibly as low as 0 ppm of the element or material. It is noted that while the presence of cerium oxide is preferred in many embodiments of this invention, it is not required in all embodiments and indeed is intentionally omitted in many instances. However, in certain example embodiments of this invention, small amounts of erbium oxide may be added to the glass in the colorant portion (e.g., from about 0.1 to 0.5% erbium oxide).

The total amount of iron present in the glass batch and in the resulting glass, i.e., in the colorant portion thereof, is expressed herein in terms of Fe₂O₃ in accordance with standard practice. This, however, does not imply that all iron is actually in the form of Fe₂O₃ (see discussion above in this regard). Likewise, the amount of iron in the ferrous state (Fe⁺²) is reported herein as FeO, even though all ferrous state iron in the glass batch or glass may not be in the form of FeO. As mentioned above, iron in the ferrous state (Fe²⁺; FeO) is a blue-green colorant, while iron in the ferric state (Fe³⁺) is a yellow-green colorant; and the blue-green colorant of ferrous iron is of particular concern, since as a strong colorant it introduces significant color into the glass which can sometimes be undesirable when seeking to achieve a neutral or clear color.

While the AR coatings discussed above are used in the context of the solar cells/modules, this invention is not so limited. AR coatings according to this invention may be used in other applications such as for picture frames, fireplace doors, and the like. Also, other layer(s) may be provided on the glass substrate under the AR coating so that the AR coating is considered on the glass substrate even if other layers are provided therebetween.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

1. A method of making a solar cell/module, the method comprising:
providing a glass substrate;
providing a colloidal silica solution comprising particulate and/or colloidal silica in at least one solvent;
providing a polymeric solution comprising silica chains and/or polymers;
mixing the colloidal silica solution and the polymeric solution comprising silica chains and/or polymers to form a coating solution;
depositing the coating solution on the glass substrate;
curing the coating solution to form an anti-reflective coating on the glass substrate, said curing comprising heating the coating solution; and
using the glass substrate with the anti-reflective coating provided thereon in a solar cell/module.

2. The method of claim 1, further comprising providing first and second conductive layers with at least a photoelectric film provided therebetween; providing the glass substrate at an incident side of the solar cell/module, the glass substrate supporting the antireflective coating on an incident side of the glass substrate; and wherein the antireflective coating comprises a porous silica based layer.

3. The method of claim 1, wherein the antireflective coating has a refractive index (n) of from about 1.2 to 1.35.

4. The method of claim 1, wherein the colloidal silica solution comprises from about 1-50% (by weight) SiO₂.

5. The method of claim 1, wherein the polymeric solution comprises from about 25-90% solvent, and from about 5-50% of a silane.

6. The method of claim 5, wherein the silane comprises trimethoxysilane.

7. The method of claim 1, wherein the antireflective coating is provided directly on and contacting the glass substrate.

8. The method of claim 1, wherein the glass substrate is of a composition comprising:

| Ingredient | wt. % |
|---|---|
| SiO₂ | 67-75% |
| Na₂O | 10-20% |
| CaO | 5-15% |
| total iron (expressed as Fe₂O₃) | 0.001 to 0.06% |
| cerium oxide | 0 to 0.30% |

wherein the glass substrate by itself has a visible transmission of at least 90%, a transmissive a* color value of −1.0 to +1.0 and a transmissive b* color value of from 0 to +1.5.

9. The method of claim 1, wherein the glass substrate is a patterned glass substrate, wherein at least one surface of the patterned glass substrate has a surface roughness of from about 0.1 to 1.5 μm; and wherein the glass substrate is of a composition comprising:

| Ingredient | wt. % |
|---|---|
| SiO₂ | 67-75% |
| Na₂O | 10-20% |
| CaO | 5-15% |
| total iron (expressed as Fe₂O₃) | 0.001 to 0.06% |
| cerium oxide | 0 to 0.07% |
| antimony oxide | 0.01 to 1.0% |

wherein the glass substrate by itself has visible transmission of at least 90%, a transmissive a* color value of −1.0 to +1.0 and a transmissive b* color value of from 0 to +1.5.

10. The method of claim 1, wherein the antireflective coating has approximately a quarter wave thickness.

11. The method of claim 1, wherein the antireflective coating has a density of from about 50-90% of a sputter-deposited layer of silica.

12. The method of claim 1, wherein the antireflective coating increases energy output of the solar cell/module by at least 1.5% compared to if the glass substrate was uncoated on the incident side thereof.

13. A solar cell/module comprising:
first and second conductive layers with at least a photoelectric film provided therebetween;
a glass substrate provided at an incident side of the solar cell/module, the glass substrate supporting an antireflective coating on an incident side of the glass substrate; and
wherein the antireflective coating comprises a porous silica based layer.

14. The solar cell/module of claim 13, wherein the antireflective coating has a refractive index (n) of from about 1.2 to 1.40.

15. The solar cell/module of claim 13, wherein the antireflective coating is provided directly on and contacting the glass substrate.

16. The solar cell/module of claim 13, wherein the glass substrate taken by itself has a visible transmission of at least about 90% and contains from about 0.001 to 0.06% total iron.

17. The solar cell/module of claim 13, wherein the glass substrate is of a composition comprising:

| Ingredient | wt. % |
|---|---|
| SiO₂ | 67-75% |
| Na₂O | 10-20% |
| CaO | 5-15% |
| total iron (expressed as Fe₂O₃) | 0.001 to 0.06% |
| cerium oxide | 0 to 0.30% |

wherein the glass substrate by itself has a visible transmission of at least 90%, a transmissive a* color value of −1.0 to +1.0 and a transmissive b* color value of from 0 to +1.5.

18. The solar cell./module of claim 13, wherein the antireflective coating has approximately a quarter wave thickness.

19. The solar cell/module of claim 13, wherein the antireflective coating has a density of from about 30-95% of a sputter-deposited dense layer of silica.

20. The solar cell/module of claim 13, wherein the antireflective coating increases energy output of the solar cell/module by at least 1.5% compared to if the glass substrate was uncoated on the incident side thereof.

21. The solar cell/module of claim 13, wherein the antireflective coating increases energy output of the solar cell by at least 3.0% compared to if the glass substrate was uncoated on the incident side thereof.

22. A method of making a solar cell/module, the method comprising:
providing a glass substrate;
coating the glass substrate with a sol-gel based silica precursor, and then subjecting the sol-gel to drying and baking so that following drying and baking an antireflective layer is present comprising a porous silica; and
using the glass substrate coated with the antireflective layer in making a solar cell/module comprising first and second conductive layers with at least a photoelectric film provided therebetween, wherein the antireflective layer is provided on an incident side of the solar cell/module.

23. The method of claim 22, wherein the antireflective layer has a refractive index of from about 1.2 to 1.4.

24. The method of claim 22, wherein the glass substrate taken by itself has a visible transmission of at least about 90% and contains from about 0.001 to 0.06% total iron.

25. A method of making a coated article, the method comprising:
providing a glass substrate;
providing a colloidal silica solution comprising particulate and/or colloidal silica in at least one solvent;
providing a polymeric solution comprising silica chains;
mixing the colloidal silica solution and the polymeric solution comprising silica chains to form a coating solution;
depositing the coating solution on the glass substrate; and
curing the coating solution to form an anti-reflective coating on the glass substrate, said curing comprising heating the coating solution.
